(19) United States
(12) Patent Application Publication
(10) Pub. No.: US 2015/0207008 A1
(43) Pub. Date: Jul. 23, 2015

(54) MULTILAYER STRUCTURE FOR THERMOPHOTOVOLTAIC DEVICES AND THERMOPHOTOVOLTAIC DEVICES COMPRISING SUCH

(71) Applicant: Triangle Resource Holding (Switzerland) AG, Zug (CH)

(72) Inventors: Reto Holzner, Zurich (CH); Urs Weidmann, Cham (CH)

(21) Appl. No.: 14/420,755

(22) PCT Filed: Aug. 12, 2013
(86) PCT No.: PCT/EP2013/066799

§ 371 Date: Feb. 10, 2015

(30) Foreign Application Priority Data
Aug. 13, 2012 (EP) 12180327.4

(51) Int. Cl. H01L 31/054

(52) U.S. Cl. CPC H01L 31/0549

(57) ABSTRACT

A multilayer structure (10) for thermophotovoltaic devices, comprising a heat transfer-emitter unit (2) and a spectral shaper (3). The heat transfer-emitter unit (2) comprising a chamber enclosure (2.1) made of a high temperature resistant material, defining a flow-through heat transfer chamber (2.2); an electro-magnetic radiation emitter (2.3) configured for emitting predominantly near-infrared radiation when exposed to high temperatures. The spectral shaper (3) is arranged adjacent to and thermally connected with said electro-magnetic radiation emitter (2.3), wherein the spectral shaper (3) is configured as a band pass filter for an optimal spectral band of the radiation and as a reflector for further, non-optimal spectral band(s) of the radiation, so that said second, non-optimal spectral band radiation is recycled as radiation redirected towards the electro-magnetic radiation emitter (2.3).

### FIELD OF THE INVENTION

The present invention relates to a multilayer structure for thermophotovoltaic devices and thermophotovoltaic devices comprising such a multilayer structure.

### BACKGROUND OF THE INVENTION

With the high demand of electricity and even more of clean, CO₂ neutral energy sources, the efficiency with which the energy is harvested plays a more and more important role. As gradually many industrialized countries aim for shifting away from nuclear power production, the demand for alternative energy sources is greater than ever. However, so far few if any really viable alternatives are known. Many of the “classical” renewable energy sources such as wind-turbines or solar power plants have significant drawbacks preventing their wide-spreading.

Still, even if these drawbacks of “classical” renewable energy sources such as wind-turbines or solar power plants would be solved, there is still the major problem that quite often these sources of renewable energy are available at a very different location than where the electrical energy is needed. The great distances between the generation location and the energy consumers require very complex, expensive and environmentally unfriendly infrastructure to transport the produced electrical energy. Furthermore, regardless of the improvements of such infrastructures in the latest period, there are still significant losses in the transport of electrical energy over long distances. Therefore there is an urgent need for decentralized energy production. In other words, the future of energy production lies in producing energy as close as possible to the consumer. This not only reduces/eliminates transmission losses but relives the electrical grid while ensuring much higher levels of flexibility.

On of the fields of great interest for decentralized energy production is the field of thermophotovoltaic devices, devices designed to transform chemical energy stored in a fuel into electro-magnetic radiation and then into electricity. However, the relatively reduced efficiency of the existing thermophotovoltaic devices has limited their use and mass-deployment.

Furthermore there is an increasing demand for mobile energy carriers/generators, ranging from portable electronic devices to electrically-powered heavy machinery. There is also a need for multi-purpose energy generators, providing for selective or simultaneous generation of heat; and/or light and/or electric.

As for efficiency, the most problematic aspect efficiency of these chemical-to-electric energy converters is one side the inefficiency of the conversion of chemical energy into electro-magnetic radiation and on the other hand the inefficiency of the conversion of the electro-magnetic radiation into electricity.

### Technical Problem to be Solved

The objective of the present invention is thus to provide a multilayer structure for thermophotovoltaic device enabling a highly efficient transformation of chemical energy into electricity by means of a thermophotovoltaic element.

A further objective of the present invention is to provide a thermophotovoltaic device comprising such a multilayer structure.

An even further objective of the present invention is to provide a thermophotovoltaic system for selective and/or simultaneous generation of heat, light and electricity.

### SUMMARY OF THE INVENTION

The above-identified objectives of the present invention are solved by a multilayer structure for thermophotovoltaic devices, comprising a heat transfer-emitter unit with a chamber enclosure made of a high temperature resistant preferably ceramic material, the chamber enclosure defining a flow-through heat transfer chamber, the chamber enclosure having at least one inner surface and one outer surface. The multilayer structure further comprising an electro-magnetic radiation emitter arranged adjacent to and thermally connected with the outer surface of said chamber enclosure, the electro-magnetic radiation emitter being configured for emitting predominantly near-infrared radiation when exposed to high temperature via said thermal connection with said chamber enclosure and a spectral shaper arranged with an input surface adjacent to and thermally connected with said electro-magnetic radiation emitter. The spectral shaper being configured as a band pass filter for a first, optimal spectral band of the radiation emitted by the electro-magnetic radiation emitter when exposed to high temperature; and/or being configured as a reflector for further, non-optimal spectral band(s) of the radiation emitted by the electro-magnetic radiation emitter, so that said second, non-optimal spectral band radiation is recycled as radiation redirected towards the electro-magnetic radiation emitter. The multilayer structure is preferably provided with means to concentrate the combustion process of a chemical energy carrier (fuel) to the surface of the flow-through heat transfer chamber.

Said further objectives of the present invention are solved by a thermophotovoltaic device comprising such a multilayer structure and a photovoltaic cell arranged adjacent to said multilayer structure in a radiating direction of its electro-magnetic radiation emitter.

The even further objectives of the invention are solved by thermophotovoltaic system comprising such a thermophotovoltaic device and a fuel source arranged such as to direct a combustible fuel mixture from the fuel source towards an input side of the flow-through heat transfer chamber, wherein the fuel source and/or the flow-through heat transfer chamber are configured such that the combustion is essentially limited to the surface of the heat transfer-emitter unit and so that combustion of the fuel mixture in the gas phase is minimized.

### Advantageous Effects

The most important advantage of the present invention is that achieves a very high efficiency by optimizing all stages of the energy conversion to minimize losses in each stage:
I) Conversion of chemical energy into thermal radiation: By concentrating the combustion process of the chemical energy carrier (fuel) to the surface of the flow-through heat transfer chamber and/or suppressing the combustion reactions in the gas phase, the heat and thus energy transfer between the fuel and the heat transfer-emitter unit is maximized while heat losses as exhaust gases are minimized;
II) Conversion of thermal energy into electro-magnetic radiation: By the use of an appropriate structure for a heat transfer-emitter unit comprising the electro-magnetic radiation emitter configured for emitting predominantly near-infrared radiation, the amount of thermal energy transformed into electro-magnetic radiation is maximized;
III) Shaping the spectrum of the electro-magnetic radiation and recycling eventual losses:
   By the use of the spectral shaper configured as a band pass filter for a first, optimal spectral band of the radiation; and/or
   By providing the spectral shaper with a self emitting material, such as Ytterbium-oxide Yb2O3 or Platinum the spectrum of the electro-magnetic radiation emitted is shaped for efficient transformation of the electro-magnetic radiation into electric energy by a photovoltaic cell.
In addition, by configuring the spectral shaper as a reflector for further, non-optimal spectral band(s) of the radiation emitted by the electro-magnetic radiation emitter, non-optimal spectral band radiation is recycled as radiation redirected towards the electro-magnetic radiation emitter further minimizing losses.

### BRIEF DESCRIPTION OF THE DRAWINGS

Further characteristics and advantages of the invention will in the following be described in detail by means of the description and by making reference to the drawings. Which show:

FIG. 1 a schematic cross-sectional diagram of a multilayer structure according to the present invention;

FIG. 2 a schematic top view of a multilayer structure comprising a heat transfer-emitter unit with a spectral shaper attached to it;

FIG. 3A a schematic perspective view of the heat transfer-emitter unit with a first embodiment of the electro-magnetic radiation emitter;

FIG. 3B a schematic perspective view of the heat transfer-emitter unit with a second embodiment of the electro-magnetic radiation emitter;

FIG. 4 a schematic top view of a further embodiment of the multilayer structure with a spectral shaper attached to it;

FIG. 5 a schematic top view of an even further embodiment of the multilayer structure with a spectral shaper attached to it;

FIG. 6A a schematic top view of a further embodiment of heat transfer-emitter unit with multiple flow-through heat transfer chambers;

FIG. 6B a schematic top view of a further embodiment of the heat transfer-emitter unit with multiple flow-through heat transfer chambers;

FIG. 6C a schematic perspective view of a further embodiment of heat transfer-emitter unit with multiple flow-through heat transfer chambers;

FIG. 7 a schematic cross-sectional diagram of a photovoltaic cell according to the present invention;

FIG. 8A a schematic cross-sectional diagram of a thermophotovoltaic device according to the present invention;

FIG. 8B a schematic perspective view of a preferred embodiment of the thermophotovoltaic device of the present invention;

FIG. 9 a schematic top view of a further embodiment of the thermophotovoltaic device;

FIG. 10 a schematic top view of an even further embodiment of the thermophotovoltaic device;

FIG. 11 a schematic perspective view of a thermophotovoltaic system according to the present invention.

Note: The figures are not drawn to scale, are provided as illustration only and serve only for better understanding but not for defining the scope of the invention. No limitations of any features of the invention should be implied form these figures.

### DESCRIPTION OF PREFERRED EMBODIMENTS

Certain terms will be used in this patent application, the formulation of which should not be interpreted to be limited by the specific term chosen, but as to relate to the general concept behind the specific term.

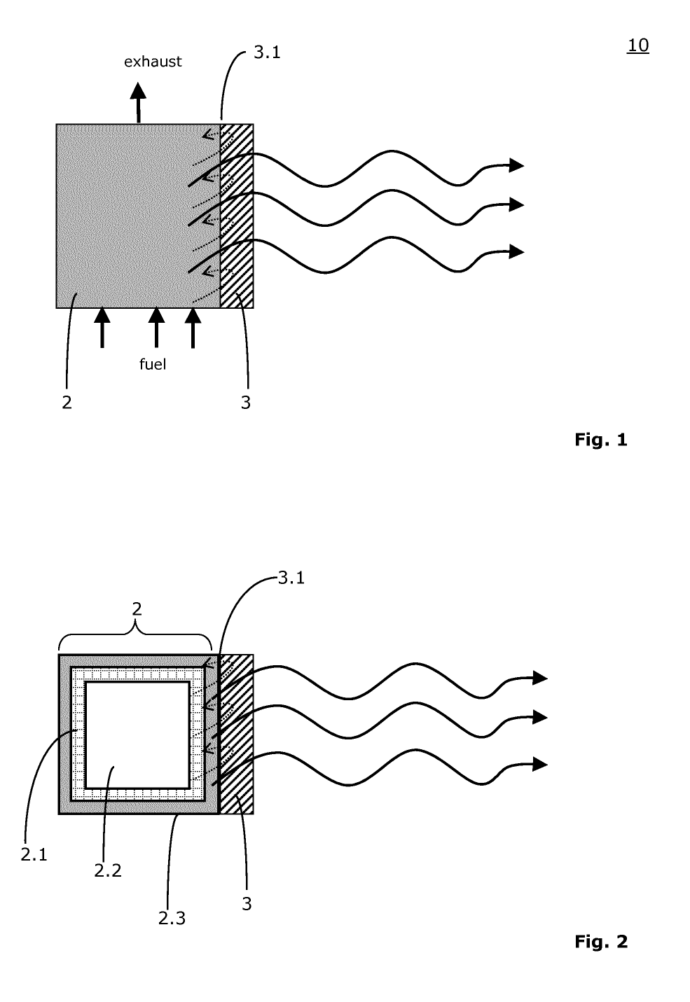

FIG. 1 shows a schematic cross-sectional diagram of a multilayer structure 10 according to the present invention. The main functional elements of the multilayer structure 10 are the heat transfer-emitter unit 2 and the spectral shaper 3.

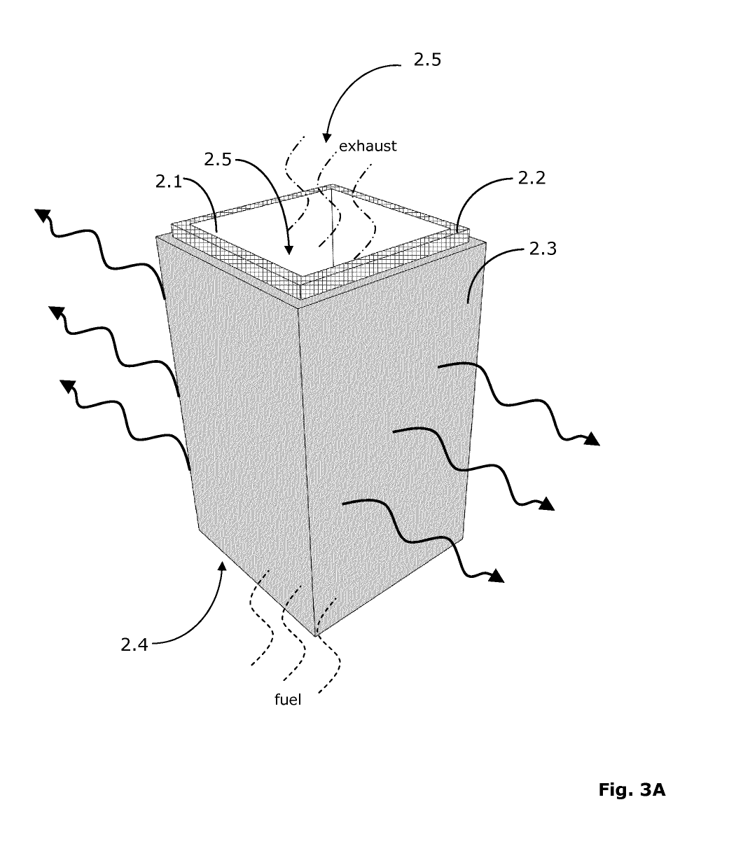

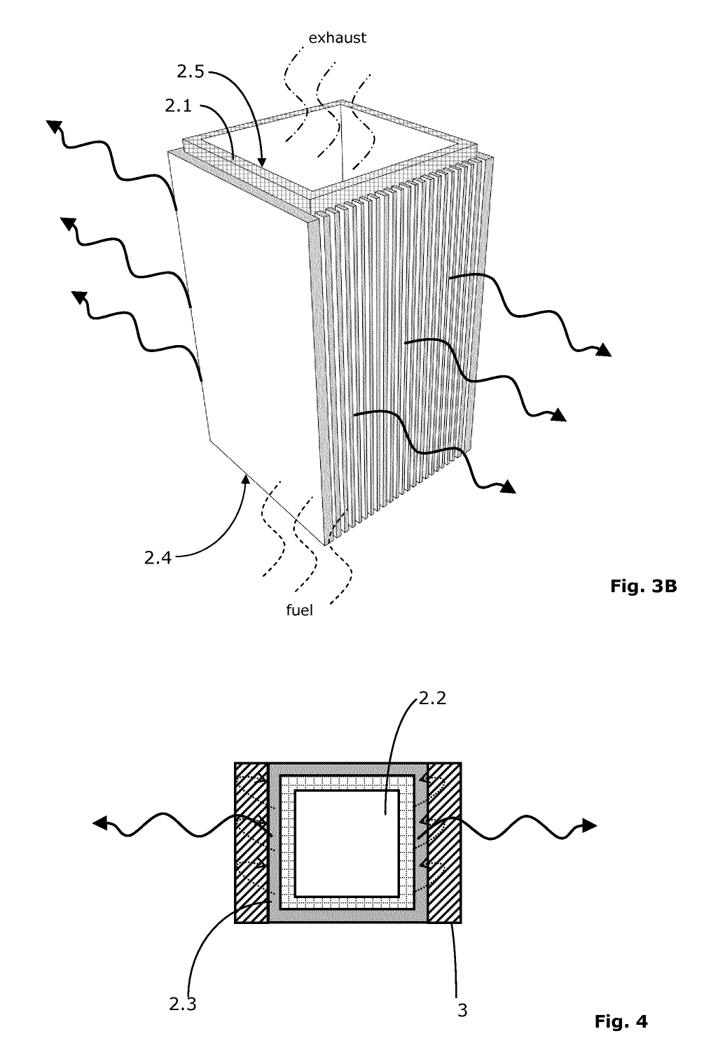

The heat transfer-emitter unit 2 comprises a chamber enclosure 2.1 made of a high temperature resistant material, preferably a ceramic material. As exemplary shown on FIGS. 2 through 3B, the chamber enclosure 2.1, having at least one inner surface and one outer surface, defines a flow-through heat transfer chamber 2.2.

As shown on FIG. 1 as well, the other main functional element of the multilayer structure, the spectral shaper 3 is arranged with an input surface adjacent to and thermally connected with said electro-magnetic radiation emitter 2.3.

The spectral shaper 3 has the following functions:
Act as a band pass filter for a first, optimal spectral band of the radiation emitted by the electro-magnetic radiation emitter 2.3 when exposed to high temperature. This is illustrated in the figures with waving arrows with continuous lines;
Act as a reflector for further, non-optimal spectral band(s) of the radiation emitted by the electro-magnetic radiation emitter 2.3, so that said second, non-optimal spectral band radiation is recycled as radiation redirected towards the electro-magnetic radiation emitter 2.3. This is illustrated in the figures with arrows drawn with dotted-lines; and/or
According to a particularly advantageous embodiment, act as an emitter itself, the spectral shaper 3 comprising a layer of selective emitter material such as a rare-earth containing layer, preferably an Ytterbium-oxide Yb₂O₃ or Platinum emitter layer and/or a nanostructured filter layer.

FIG. 2 depicts a schematic top view of the multilayer structure comprising 10 depicting how a spectral shaper 3 is attached to a heat transfer-emitter unit 2. A further essential element of the heat transfer-emitter unit 2 is the electro-magnetic radiation emitter 2.3 which is arranged adjacent to and thermally connected with the outer surface of said chamber enclosure 2.1. The electro-magnetic radiation emitter 2.3 is configured for emitting predominantly near-infrared radiation when exposed to high temperatures via said thermal connection with said chamber enclosure 2.1. FIG. 2 illustrates symbolically (with waving arrows) the radiating direction of electro-magnetic radiation from the electro-magnetic radiation emitter 2.3.

Optionally, a barrier layer 3.1 which is transparent particularly to near infrared radiation—preferably a quartz barrier layer 3.1—is provided between the heat transfer-emitter unit 2 and the spectral shaper 3 in order to provide a heat conduction barrier as well as to account for possible heat expansion induced forces and to even better filter out/reflect all non-optimal spectral band(s) of the radiation emitted by the electro-magnetic radiation emitter 2.3, so that said second, non-optimal spectral band radiation is recycled as radiation redirected towards the electro-magnetic radiation emitter 2.3.

FIG. 3A shows a schematic perspective view of the heat transfer-emitter unit 2 with a first embodiment of the electro-magnetic radiation emitter 2.3.

An in-flow of combustible fuel mixture at said input side 2.4 of the flow-through heat transfer chamber 2.2 is shown on the figures with waving dashed lines, while the out-flow of exhaust gases at said exhaust side 2.5 of the flow-through heat transfer chamber 2.2 is shown with dotted-dashed waving lines.

The chamber enclosure 2.1 is made of a high temperature resistant—preferably ceramic—material configured to provide sufficient stability to the electro-magnetic radiation emitter 2.3. Also, the chamber enclosure 2.1 distributes the heat from the flow-through heat transfer chamber 2.2 evenly to the electro-magnetic radiation emitter 2.3 such as to cause the later to emit electro-magnetic radiation.

In a preferred embodiment of the invention, the inner surface of the heat transfer chamber 2.2 is provided with means to concentrate the combustion process of a chemical energy carrier (fuel) to the surface of the flow-through heat transfer chamber 2.2, in order to maximize heat transfer between a chemical energy carrier (fuel) within the heat transfer chamber 2.2 and the chamber enclosure 2.1 respectively the electro-magnetic radiation emitter 2.3. Said means to concentrate the combustion process of a chemical energy carrier (fuel) to the surface is preferably achieved by means of a catalytic coating on the inner surface of the flow-through heat transfer chamber 2.2.

FIG. 3B shows a schematic perspective view of the heat transfer-emitter unit 2 with a second embodiment of the electro-magnetic radiation emitter 2.3. According to this embodiment, the electro-magnetic radiation emitter 2.3 comprises fin-like structures extending outwards from the heat transfer-emitter unit 2, the fin-like structures being provided to maximize the radiating surface of the electro-magnetic radiation emitter 2.3. These fin-like structures can be various two- or three-dimensional structures and may extend from the nanoscale to the macroscopic scale.

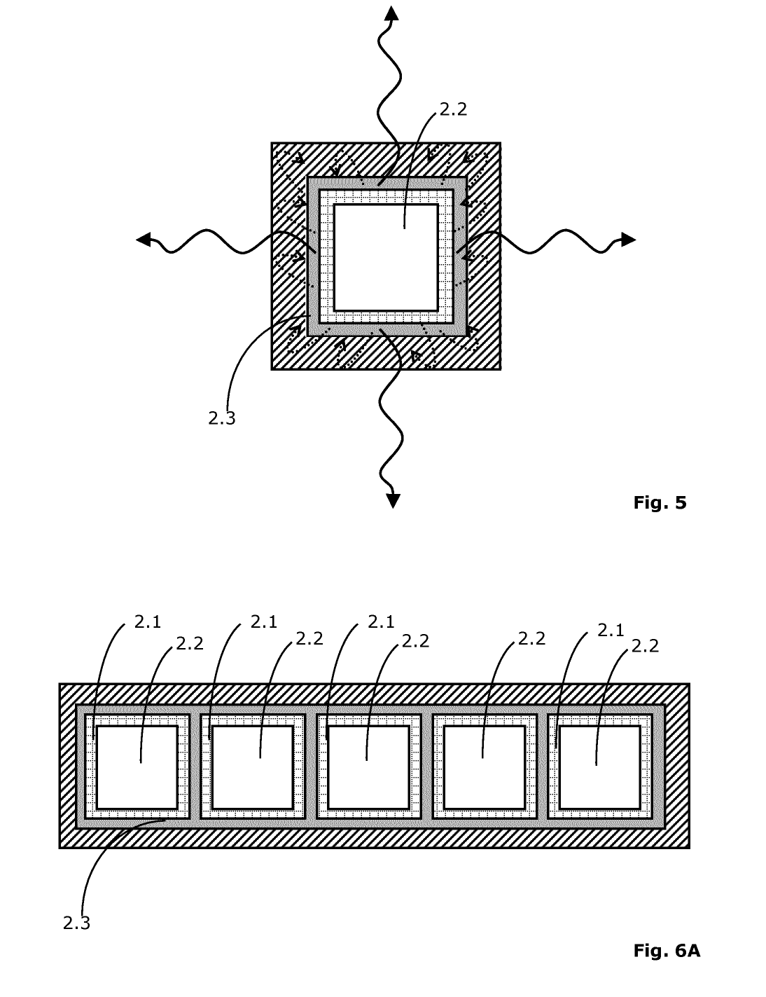

FIG. 4 depicts a schematic top view of a functionally and structurally symmetric embodiment of the multilayer structure 10 with a symmetric spectral shaper 3 attached on opposite sides of a symmetric heat transfer-emitter unit 2, wherein the electro-magnetic radiation emitter 2.3 is arranged to emit predominantly near-infrared radiation in two opposing directions. The embodiment shown on FIG. 4 is a bilaterally symmetric embodiment, whereas FIG. 5 shows a schematic top view of an even further embodiment of the multilayer structure 10 arranged in a cross shape, with the spectral shaper 3 arranged in each direction of the cross. The multilayer structure 10 may have the shape of other symmetrical (e.g. hexagonal, octagonal, elliptical spherical) or non symmetrical bodies.

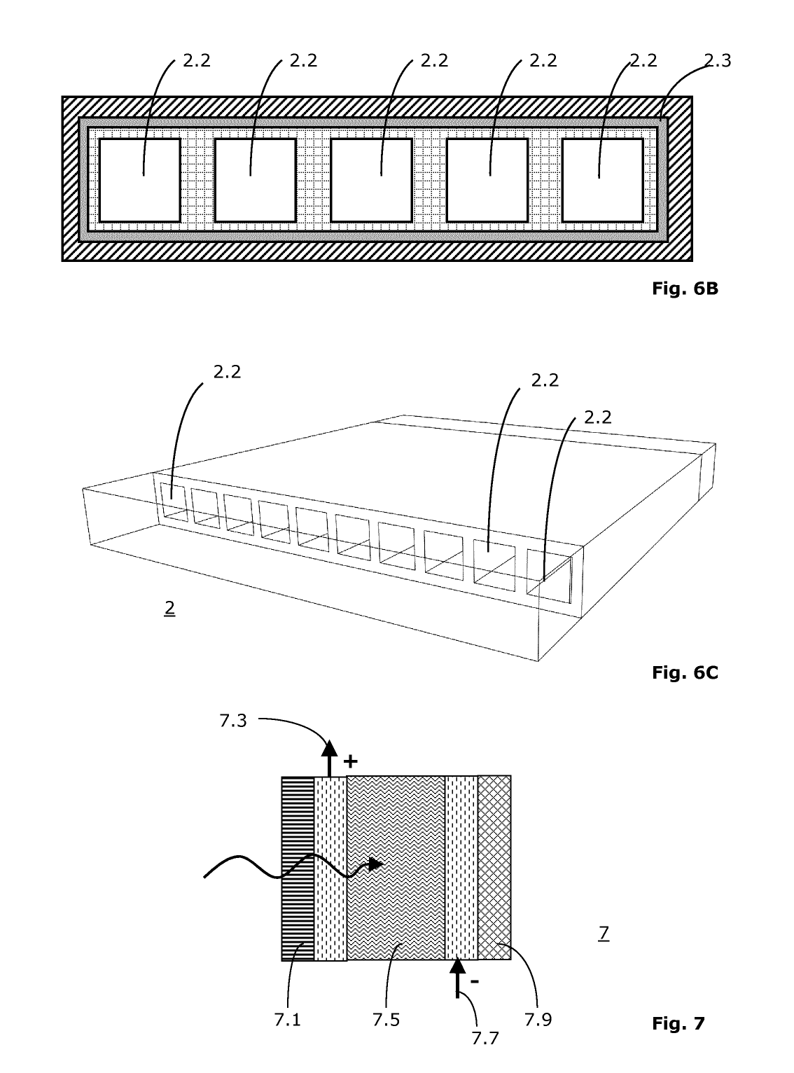

FIGS. 6A and 6B show schematic top views of various embodiments of heat transfer-emitter unit 2 with multiple flow-through heat transfer chambers 2.2.

FIG. 6C shows a schematic perspective view of the further embodiment of heat transfer-emitter unit 2 with multiple flow-through heat transfer chambers 2.1 of FIG. 6B.

FIG. 7 shows a schematic cross-sectional diagram of an exemplary photovoltaic cell 7 according to the present invention, which shall be arranged adjacent to said multilayer structure 10 in a radiating direction of its electro-magnetic radiation emitter 2.3 (as shown in following figures). The radiating direction of its electro-magnetic radiation emitter 2.3 is illustrated with a waving arrow. The photovoltaic cell 7 comprises a conversion area 7.5 arranged in the radiating direction of the spectral shaper 3 and/or the electro-magnetic radiation emitter 2.3 of the multilayer structure 10. The photovoltaic cell 7 is optimized for predominantly near-infrared radiation in order to improve the efficiency of transforming the “spectral shaped” radiation from the multilayer structure 10 into electric energy.

In its most preferred embodiment (as shown on FIG. 7), the photovoltaic cell 7 comprises an anti-reflection layer 7.1 situated on a first surface of the conversion area 7.5 directed towards said radiating direction of the spectral shaper 3 and/or the electro-magnetic radiation emitter 2.3 of the multilayer structure 10. In a particularly preferred embodiment, the anti-reflection layer 7.1 comprises a plasmonic filter configured to act as an anti-reflection layer for radiation at a predefined wavelengths while reflecting radiation outside said predefined wavelength. For example the anti-reflection layer 7.1 comprises a thin metal film—preferably gold—which is perforated with an array of sub-wavelength holes. The holes are spaced periodically, so that diffraction can excite surface plasmons when the film is irradiated. The surface plasmons then transmit energy through the holes and re-radiate on the opposite side of the film. The spacing of the holes is determined based on the wavelength of the emission to be transmitted through the anti-reflection layer 7.1.

Furthermore, the photovoltaic cell 7 comprises a reflective layer 7.9 on a second surface of the conversion area 7.5 situated on an opposite direction as said first surface. Additionally electrical back plane contacts 7.7 are located for example between said conversion area 7.5 and said reflective layer 7.9 and wherein electrical front plane contacts 7.3 are located for example between said anti-reflection layer 7.1 and the conversion area 7.5. Alternatively (not shown on this figure), both electrical front- and back-plane contacts may be arranged either between said conversion area 7.5 and said reflective layer 7.9, or both between said anti-reflection layer 7.1 and the conversion area 7.5.

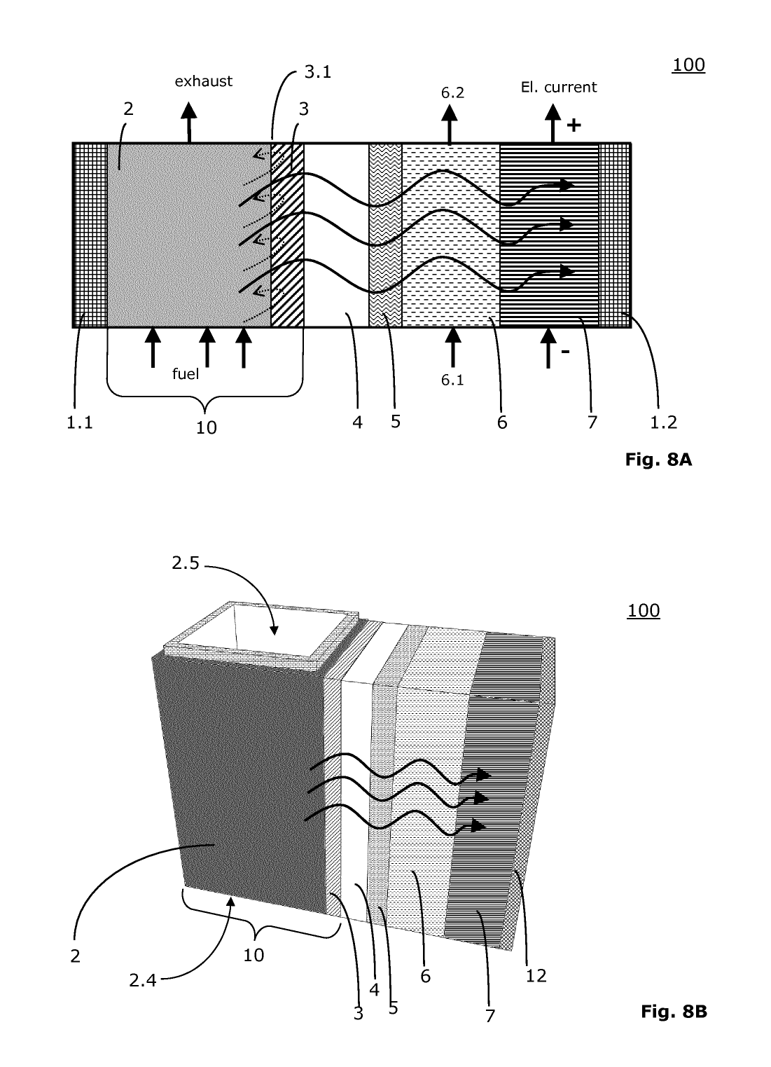

FIGS. 8A and 8B show a schematic cross-sectional diagram respectively a perspective view of a thermophotovoltaic device 100 according to the present invention, comprising a multilayer structure 10 (as hereinbefore described) and a photovoltaic cell 7 (as hereinbefore described) arranged adjacent to said multilayer structure 10 in a radiating direction of its electro-magnetic radiation emitter 2.3.

As shown on FIGS. 8A and 8B, in a preferred embodiment, a heat conduction barrier 4, e.g. in the form of a vacuum or aerogel layer or quartz plate is provided between said spectral shaper 3 and the photovoltaic cell 7. In an even further embodiment, a spectral filter 5 is provided between the spectral shaper 3 of the multilayer structure 10 and the photovoltaic cell 7.

For cooling of the thermophotovoltaic device 100 and or for providing a heating function, an active cooling layer 6 is provided between the spectral shaper 3 of the multilayer structure 10 and the photovoltaic cell 7 and/or at a back side of the photovoltaic cell 7 directed in opposite direction as the spectral shaper 3, wherein said active cooling layer 6 comprises a cooling agent, such as water or other coolant between a cooling agent input 6.1 and a cooling agent output 6.2. The cooling layer 6 is configured so as to absorb lower wavelength radiation emitted by the spectral shaper 3 and/or the electro-magnetic radiation emitter 2.3 of the multilayer structure 10, providing cooling to the photovoltaic cell 7 by thermal connection.

A cooling layer, optimized for contact cooling, may be located behind the total reflector 1.1 respectively 1.2 in addition to other cooling measures or stand alone.

In order to improve the radiation absorption of the cooling layer 6, micro-channels are provided in the cooling layer 6, connecting said cooling agent input 6.1 and said cooling agent output 6.2.

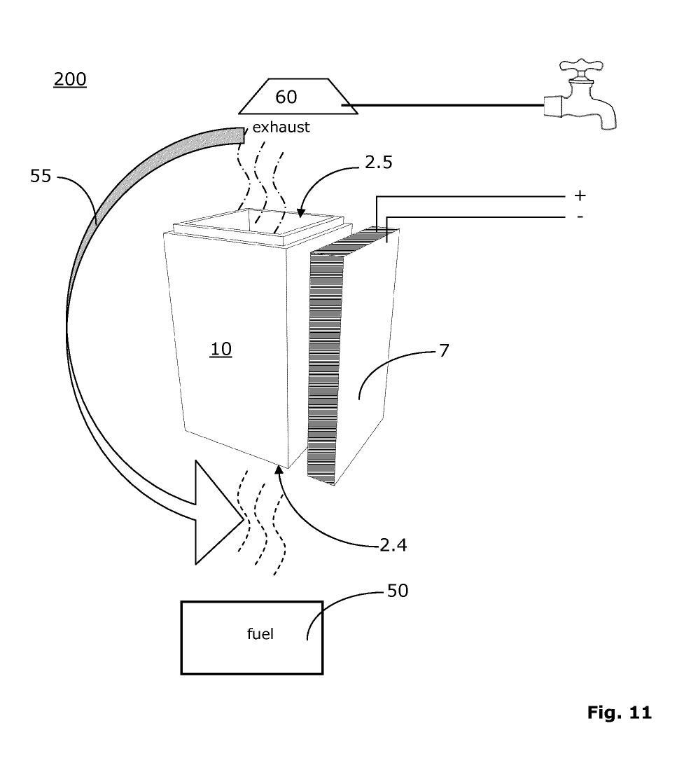

However this active cooling layer 6 may be employed to provide a heating function as well by warming up a cooling agent or simply water at the cooling agent input 6.1, thereby providing heat at the cooling agent output 6.2. This option shall be exploited in a thermophotovoltaic system 200 (described in following paragraphs with reference to FIG. 11).

In further embodiments (not shown on the figures), the spectral shaper 3 and/or the photovoltaic cell 7; and/or the barrier layer 3.1; and/or the heat conduction barrier 4 are configured as open cylindroids, preferably open cylinders preferably arranged coaxially around the electro-magnetic radiation emitter 2. Polygonal structures are also possible. The thermophotovoltaic device 100 may have the shape of other symmetrical (e.g. hexagonal, octagonal, elliptical spherical) or non symmetrical bodies.

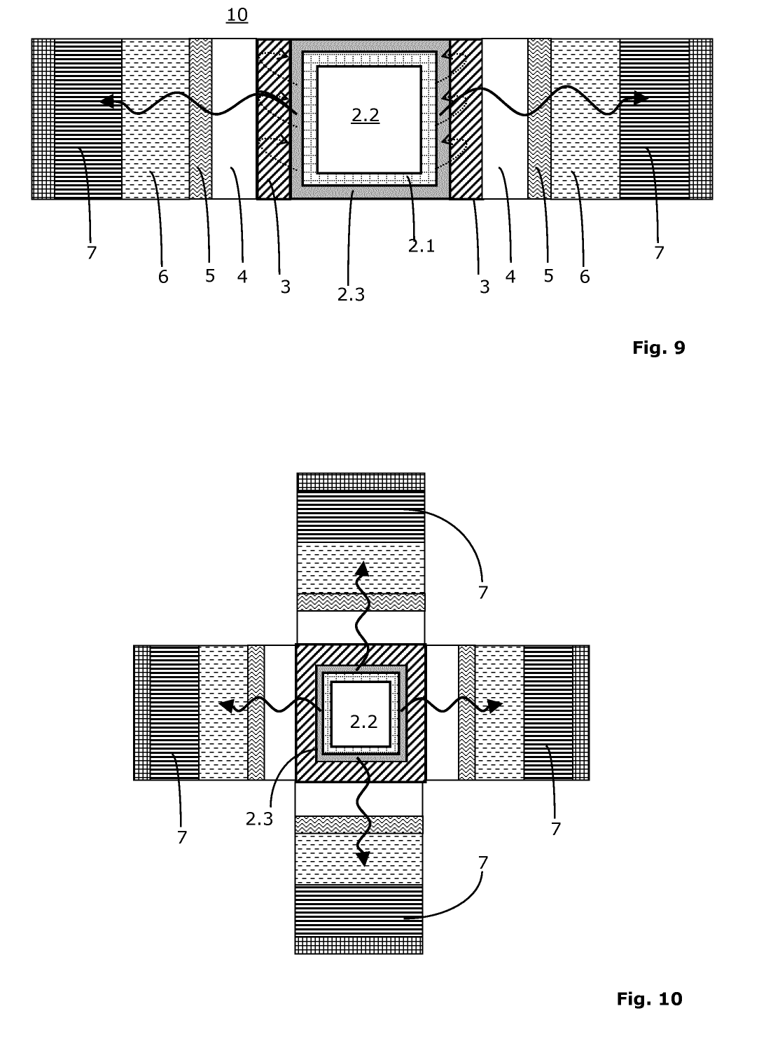

FIG. 9 shows a schematic top view of a further embodiment of the thermophotovoltaic device 100, arranged structurally and functionally symmetrical with respect to the heat transfer-emitter unit 2 with at one photovoltaic cell 7 in each direction of symmetry. The multilayer structure 10, the spectral shaper 3 as well as the other optional layers are attached are on opposite sides of a symmetric heat transfer-emitter unit 2 with its electro-magnetic radiation emitter 2.3 arranged to emit predominantly near-infrared radiation in two opposing directions.

The embodiment shown on FIG. 9 is a bilaterally symmetric embodiment, whereas FIG. 10 shows a schematic top view of an even further embodiment of the thermophotovoltaic device 100 arranged in a cross shape, with the spectral shaper 3 and a photovoltaic cell 7 arranged in each direction of the cross.

One shall note that the thermophotovoltaic device 100 must not be completely symmetrical, certain layers (such as the barrier layer 3.1, the heat conduction barrier 4, the spectral filter 5 or the active cooling layer 6) being provided on one but not the other directions. In a thermophotovoltaic system 200 (described in following paragraphs with reference to FIG. 11) configured as a portable energy source such as to simultaneously or selectively act as a heat source, a source of electric energy and a light source, an arrangement of the thermophotovoltaic device 100 can be realized, wherein each “arm” of the cross is optimized for one or more of the functionalities of the multifunctional thermophotovoltaic system 200. Thus the thermophotovoltaic system 200 can selectively or simultaneously provide:
heat radiation from the thermal energy source 50 and/or the flow-through heat transfer chamber 2.2 and/or through the cooling agent output (6.2) of the cooling layer (6);
electric energy at an output terminal of the photovoltaic cell 7;
light, i.e. electro-magnetic radiation in the visible spectrum.
   Therefore such a thermophotovoltaic system 200 is very flexible regards the form of energy provided while being very efficient in each operating mode (heat/electricity/light source).

FIG. 11 depicts a schematic perspective view of a thermophotovoltaic system 200 according to the present invention comprising a thermophotovoltaic device 100 (as hereinbefore described) and a fuel source 50, arranged such as to direct a combustible fuel mixture from the fuel source 50 towards the input side 2.4 of the flow-through heat transfer chamber 2.2. The flow-through heat transfer chamber 2.2 is configured such that the combustion is essentially limited to the surface of the electro-magnetic radiation emitter 2 and so that combustion of the fuel mixture in the gas phase is minimized.

The fuel source 50 is a chemical energy source, wherein the chemical energy carrier is a fossil fuel such as Methanol.

As shown on FIG. 11, the thermophotovoltaic system 200 further comprises a waste heat recovery unit 55 configured to recover heat from exhaust gases at the exhaust side 2.5 of the flow-through heat transfer chamber 2.2 and feed back said recovered heat to said input side 2.4.

A further advantageous embodiment of the thermophotovoltaic system 200 comprises in addition a condenser unit 60 configured to recover liquid by condensing vapour in the exhaust gases at said exhaust side 2.5 of the flow-through heat transfer chamber 2.2. In case the fuel is Methanol for example, the condenser unit 60 is laid out for condensing water vapours resulting from combustion of the Methanol. In this way, the thermophotovoltaic system 200 is also capable of acting (simultaneously or selectively) as a source of pure water.

### Quantitative Example

In the specific example of Methanol as fuel, at an efficiency of about 20% a thermophotovoltaic system 200 according to the present invention combusting 1 L of Methanol, will produce:
about 1 kWh electric energy at the output terminal of the photovoltaic cell 7;
about 4 kWh heat from the thermal energy source 50 and/or the flow-through heat transfer chamber 2.2 and/or through the cooling agent output 6.2 of the cooling layer 6; and
about 1 L pure Water at an output side of the condenser unit 60.

It will be understood that many variations could be adopted based on the specific structure hereinbefore described without departing from the scope of the invention as defined in the following claims.

### REFERENCE LIST

multilayer structure 10
total reflector 1.1, 1.2
heat transfer-emitter unit 2
   chamber enclosure 2.1
   flow-through heat transfer chamber 2.2
   electro-magnetic radiation emitter 2.3
   input side 2.4
   exhaust side 2.5
spectral shaper 3
barrier layer 3.1
heat conduction barrier 4
spectral filter 5
active cooling layer 6
   cooling agent input 6.1
   cooling agent output 6.2
photovoltaic cell 7
   anti-reflection layer 7.1
   front plane contacts 7.3
   conversion area 7.5
   electrical back plane contacts 7.7
   reflective layer 7.9
thermophotovoltaic device 100
thermophotovoltaic system 200
fuel source 50
waste heat recovery unit 55
condenser unit 60

What is claimed is:

1. A multilayer structure (10) for thermophotovoltaic devices, comprising:
a heat transfer-emitter unit (2) comprising:
a chamber enclosure (2.1) made of a high temperature resistant preferably ceramic material, the chamber enclosure (2.1) defining a flow-through heat transfer chamber (2.2), the chamber enclosure (2.1) having at least one inner surface and an outer surface;
an electro-magnetic radiation emitter (2.3) arranged adjacent to and thermally connected with the outer surface of said chamber enclosure (2.1), the electro-magnetic radiation emitter (2.3) being configured for emitting predominantly near-infrared radiation when exposed to high temperature via said thermal connection with said chamber enclosure (2.1);
a spectral shaper (3) arranged with an input surface adjacent to and thermally connected with said electro-magnetic radiation emitter (2.3), wherein the spectral shaper (3):
is configured as a band pass filter for a first, optimal spectral band of the radiation emitted by the electro-magnetic radiation emitter (2.3) when exposed to high temperature; and/or
is configured as a reflector for further, non-optimal spectral band(s) of the radiation emitted by the electro-magnetic radiation emitter (2.3), so that said second, non-optimal spectral band radiation is recycled as radiation redirected towards the electro-magnetic radiation emitter (2.3).

2. A multilayer structure (10) according to claim 1, characterized in that said inner surface of the heat transfer chamber (2.2) is provided with means to concentrate the combustion process of a chemical energy carrier (fuel) to the surface of the flow-through heat transfer chamber (2.2), preferably by means of a catalytic coating in order to maximize heat transfer between a chemical energy carrier (fuel) within the heat transfer chamber (2.2) and the chamber enclosure (2.1) respectively the electro-magnetic radiation emitter (2.3).

3. A multilayer structure (10) according to claim 1, characterized in that the electro-magnetic radiation emitter (2.3) comprises structures extending outwards from the heat transfer-emitter unit (2) in a radiating direction of the electro-magnetic radiation emitter (2.3) so as to maximize its radiating surface and/or to optimize the radiation spectrum for example by photonic crystal type nanostructuring.

4. A multilayer structure (10) according to claim 1, characterized in that a barrier layer (3.1) which is transparent to near infrared radiation—preferably a quartz barrier layer (3.1)—is provided between said heat transfer-emitter unit (2) and the spectral shaper (3).

5. A multilayer structure (10) according to claim 1, characterized in that said spectral shaper (3) comprises a layer of selective emitter material such as a rare-earth containing layer, preferably an Ytterbium-oxide Yb₂O₃ or Platinum emitter layer and/or a nanostructured filter layer.

6. A thermophotovoltaic device (100) comprising:
a multilayer structure (10) according to claim 1; and
a photovoltaic cell (7) arranged adjacent to said multilayer structure (10) in a radiating direction of its electro-magnetic radiation emitter (2.3).

7. A thermophotovoltaic device (100) according to claim 6, characterized in that a heat conduction barrier (4), e.g. in the form of a vacuum or aerogel layer is provided between said spectral shaper (3) and the photovoltaic cell (7).

8. A thermophotovoltaic device (100) according to claim 6, characterized in that a spectral filter (5) is provided between the spectral shaper (3) of the multilayer structure (10) and the photovoltaic cell (7).

9. A thermophotovoltaic device (100) according to claim 6, characterized in that an active cooling layer (6) is provided between the spectral shaper (3) of the multilayer structure (10) and the photovoltaic cell (7) and/or at a back side of the photovoltaic cell (7) directed in opposite direction as the spectral shaper (3), wherein said active cooling layer (6) comprises a cooling agent, such as water or other coolant between a cooling agent input (6.1) and a cooling agent output (6.2), the cooling layer (6) being configured so as to absorb lower wavelength radiation emitted by the spectral shaper (3) and/or the electro-magnetic radiation emitter (2.3) of the multilayer structure (10), providing cooling to the photovoltaic cell (7) by thermal connection.

10. A thermophotovoltaic device (100) according to claim 9, characterized in that micro-channels are provided in the cooling layer (6), connecting said cooling agent input (6.1) and said cooling agent output (6.2) in order to improve the radiation absorption of the cooling layer (6).

11. A thermophotovoltaic device (100) according to claim 6, characterized in that the photovoltaic cell (7) comprises a conversion area (7.5)—optimized for predominantly near-infrared radiation—arranged in an radiating direction of the spectral shaper (3) and/or the electro-magnetic radiation emitter (2.3) of the multilayer structure (10).

12. A thermophotovoltaic device (100) according to claim 11, characterized in that the photovoltaic cell (7) comprises an anti-reflection layer (7.1) situated on a first surface of the conversion area (7.5) directed towards said radiating direction of the spectral shaper (3) and/or the electro-magnetic radiation emitter (2.3) of the multilayer structure (10) and a reflective layer (7.9) on a second surface of the conversion area (7.5) situated on an opposite direction as said first surface, wherein electrical back plane contacts (7.7) are located between said conversion area (7.5) and said reflective layer (7.9) and wherein electrical front plane contacts (7.3) are located between said anti-reflection layer (7.1) and the conversion area (7.5).

13. A thermophotovoltaic device (100) according to claim 6, characterized in that it is arranged structurally and/or functionally symmetrical with respect to the heat transfer-emitter unit (2) with at least one photovoltaic cell (7) in each direction of symmetry.

14. A thermophotovoltaic device (100) according to claim 13, characterized in that it is arranged in a cross shape, with at least one photovoltaic cell (7) in each direction of the cross.

15. A thermophotovoltaic device (100) according to claim 6,
characterized in that:
the spectral shaper (3); and/or
the photovoltaic cell (7); and/or
the barrier layer (3.1); and/or
the heat conduction barrier (4)
are configured as open cylindroids, preferably open cylinders preferably arranged coaxially around the electro-magnetic radiation emitter (2).

16. A thermophotovoltaic system (200) comprising:
a thermophotovoltaic device (100) according to claim 6;
a fuel source (50), arranged such as to direct a combustible fuel mixture from the fuel source (50) towards an input side (2.4) of said flow-through heat transfer chamber (2.2), configured such that the combustion is essentially limited to the surface of the heat transfer-emitter unit (2) and so that combustion of the fuel mixture in the gas phase is minimized.

17. A thermophotovoltaic system (200) according to claim 14, characterized in that said fuel source (50) is a chemical energy source, wherein the chemical energy carrier is a fossil fuel such as Methanol.

18. A thermophotovoltaic system (200) according to claim 16, characterized in that the system further comprises a waste heat recovery unit (55) configured to recover heat from exhaust gases at an exhaust side (2.5) of the flow-through heat transfer chamber (2.2) and feed back said recovered heat to said input side (2.4).

19. A thermophotovoltaic system (200) according to claim 16, characterized in that it is configured as a portable energy source such as to simultaneously or selectively:
act as a heat source providing heat radiation from the thermal energy source (50) and/or the flow-through heat transfer chamber (2.2) and/or through the cooling agent output (6.2) of the cooling layer (6);
act as a source of electric energy providing electric energy at an output terminal of the photovoltaic cell (7);
act as a light source, the electro-magnetic radiation emitter (2.3) being configured such as to provide electro-magnetic radiation in the visible spectrum when exposed to high temperature.

20. A thermophotovoltaic system (200) according to claim 19, characterized in that it further comprises a condenser unit (60) configured to recover liquid by condensing vapour in the exhaust gases at said exhaust side (2.5) of the flow-through heat transfer chamber (2.2), preferably condensing water vapours resulting from combustion of Methanol as fuel, the thermophotovoltaic system (200) thus being further configured as a source of pure water.
